(19) United States
(12) Patent Application Publication
(10) Pub. No.: US 2017/0133238 A1
(43) Pub. Date: May 11, 2017

(54) MANUFACTURING METHOD OF SEMICONDUCTOR DEVICE AND SLURRY FOR CHEMICAL MECHANICAL POLISHING

(71) Applicant: KABUSHIKI KAISHA TOSHIBA, Tokyo (JP)

(72) Inventors: Takahiko KAWASAKI, Nagoya (JP); Yukiteru Matsui, Nagoya (JP); Kenji Iwade, Hiratsuka (JP); Akifumi Gawase, Kuwana (JP)

(73) Assignee: Kabushiki Kaisha Toshiba

(21) Appl. No.: 15/228,369

(22) Filed: Aug. 4, 2016

(30) Foreign Application Priority Data
Nov. 9, 2015 (JP) 2015-219680

(51) Int. Cl. H01L 21/321; B24B 37/20; C23F 3/04; H01L 21/3105; C09G 1/02

(52) U.S. Cl. CPC H01L 21/3212; H01L 21/31053; C09G 1/02; C23F 3/04; B24B 37/20

(57) ABSTRACT

In accordance with an embodiment, a manufacturing method of a semiconductor device includes using a slurry containing a cationic water-soluble polymer (A), iron nitrate (B), and abrasive grains (C) to chemically and mechanically polish a film to be polished. The film includes an insulating film provided with a groove or a hole, and a tungsten film to fill the groove or the hole. The chemical mechanical polishing includes a first polishing process to polish the tungsten film, and a second polishing process to polish the tungsten film and the insulating film together. The second polishing process is conducted after the first polishing process. The content of the (A) component in the slurry used in the second polishing process is less than 300 ppm, and the content of the (B) component is 100 ppm or less.

### CROSS REFERENCE TO RELATED APPLICATIONS

This application is based upon and claims the benefit of priority from the prior Japanese Patent Application No. 2015-219680, filed on Nov. 9, 2015, the entire contents of which are incorporated herein by reference.

### FIELD

Embodiments described herein relate generally to a manufacturing method of semiconductor device and slurry for chemical mechanical polishing.

### BACKGROUND

In a semiconductor process, chemical mechanical polishing (hereinafter briefly referred to as “CMP”) is used to planarize films that fill wiring grooves and via holes, for example, insulating films, metallic films, and polycrystalline silicon films.

When a filling film made of a metallic material such as a tungsten film is polished by CMP, a first polishing process to polish a bulk film of tungsten, and a second polishing process to simultaneously polish a tungsten film and a surrounding film such as an oxide film are conducted. A commonly used technique ensures planarity by polishing the bulk film of tungsten at a high speed in the first polishing process, and removing the tungsten film and the oxide film in the same selectivity in the second polishing process which is a finishing process.

However, for example, in a blanket wafer, even if the planarity is ensured, loose and dense portions of patterns are scatteringly present in actual pattern wafers, which leads to the problem that satisfactory planarity cannot always be obtained, and thus, for example, great dishing is recognized in a pattern which is locally high in the occupancy of a metallic film as a result of polishing.

### BRIEF DESCRIPTION OF THE DRAWINGS

In the accompanying drawings:

FIG. 1 is an example of a partial sectional view showing an example of a substrate in which a metallic film to be a polishing target is provided;

FIG. 2 is an example of a schematic perspective view showing an example of a CMP apparatus to conduct a manufacturing method of a semiconductor device according to Embodiment 1;

FIGS. 3A to 3C are examples of partial sectional views illustrating the manufacturing method of the semiconductor device according to Embodiment 1;

FIG. 4 is an example of a graph showing the relation between the concentration of ferric nitrate and the selectivity of tungsten/silicon oxide films which are obtained regarding a blanket wafer;

FIG. 5 is an example of a schematic diagram showing an example of a pattern layout which locally varies in the occupancy of a metallic film;

FIG. 6 is an example of a graph showing an example of excessive polishing resulting from the polishing of polishing films laid out as shown in FIG. 5 wherein the concentration of ferric nitrate is under control;

FIG. 7 is an example of a schematic diagram showing another example of a pattern layout which locally varies in the occupancy of a metallic film;

FIG. 8 is an example of a graph showing an example of excessive polishing resulting from the polishing of polishing films laid out as shown in FIG. 7 wherein the concentration of ferric nitrate is under control;

FIG. 9A is an example of a schematic sectional view illustrating a factor of excessive polishing in a metallic film dense part;

FIG. 9B is an example of a schematic sectional view showing an example of excessive polishing which has taken place in the metallic film dense part due to the factor shown in FIG. 9A;

FIG. 10 is an example of a schematic sectional view illustrating how excessive polishing in the metallic film dense part is prevented by the change of the composition ratio of materials in a slurry;

FIG. 11 is an example of a graph showing an example of the relation between the PEI addition amount and the metallic film polishing rate in a first polishing process;

FIG. 12 is an example of a graph showing an example of the relation between the ferric nitrate addition amount and the metallic film dishing rate in the case where a second polishing process is conducted in a PEI addition amount of 70 ppm;

FIG. 13 is an example of a graph showing an example of the relation between the ferric nitrate addition amount and the metallic film dishing rate in the case where the second polishing process is conducted in a PEI addition amount of 140 ppm;

FIG. 14 is an example of a schematic diagram showing an example of a urethane foam pad;

FIG. 15 is an example of a table showing an example of the relation between the number of air bubbles per unit area and the polishing rate; and

FIG. 16 is an example of a graph showing examples of polishing rates according to three kinds of polishing pads shown in FIG. 15.

### DETAILED DESCRIPTION

In accordance with an embodiment, a manufacturing method of a semiconductor device includes using a slurry containing a cationic water-soluble polymer (A), iron nitrate (B), and abrasive grains (C) to chemically and mechanically polish a film to be polished. The film includes an insulating film provided with a groove or a hole, and a tungsten film to fill the groove or the hole. The chemical mechanical polishing includes a first polishing process to polish the tungsten film, and a second polishing process to polish the tungsten film and the insulating film together. The second polishing process is conducted after the first polishing process. The content of the (A) component in the slurry used in the second polishing process is less than 300 ppm, and the content of the (B) component is 100 ppm or less.

Embodiments will now be explained with reference to the accompanying drawings. Like components are provided with like reference signs throughout the drawings and repeated descriptions thereof are appropriately omitted. It is to be noted that the accompanying drawings illustrate the invention and assist in the understanding of the illustration and that the shapes, dimensions, and ratios and so on in each of the drawings may be different in some parts from those in an actual apparatus.

In the specification of the present application, terms indicating directions such as “up” and “down” in the explanation show relative directions in the case where the upper side is a processing target side of a later-described substrate, more specifically, a side in which wiring grooves and via holes are formed among the surfaces of the substrate. Therefore, the directions may be different from the actual directions based on gravitational acceleration directions.

### (1) Embodiment 1

(a) Preparation of Film to be Polished

First, a polishing target is prepared.

An example of a substrate in which a metallic film to be a polishing target is provided is shown in a schematic sectional view of FIG. 1. The polishing target shown in FIG. 1 can be prepared, for example, by forming a silicon oxide film 40 on an element formation surface of a silicon wafer W and then forming a trench for wiring or a via hole therein, forming a barrier metal into a barrier metal film 42 by, for example, sputtering, and then forming a metallic film such as a tungsten film 44 all over the surface so as to fill the trench or the via hole. The tungsten film 44 includes a tungsten film 44a in the trench or the via hole, and a tungsten film 44b on the tungsten film 44a and on the silicon oxide film 40. A tungsten oxide (WOx) film 46 is formed on the tungsten film 44b.

In the present embodiment, the silicon wafer W corresponds to, for example, a substrate. It should be understood that the substrate is not limited to the silicon wafer, and also includes, for example, a glass substrate and a ceramic substrate.

(b) Preparation of Slurry

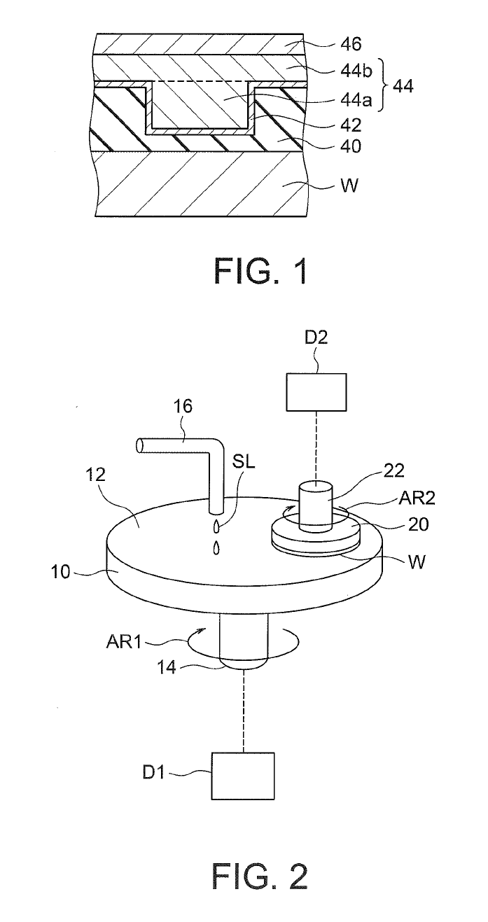

A slurry SL (see FIG. 2) is then prepared. In the present embodiment, the slurry including the same material is used in both a first polishing process to polish the bulk film 44b of tungsten, and a second polishing process to simultaneously polish the tungsten film 44a, the barrier metal film 42, and the silicon oxide film 40. However, as will be described later, the composition ratio of contained materials is changed between the first polishing process and the second polishing process.

Specifically, the slurry SL used contains a cationic water-soluble polymer (hereinafter suitably referred to as an “(A) component”), iron nitrate (hereinafter suitably referred to as a “(B) component”), and abrasive grains (hereinafter suitably referred to as a “(C) component”). In the first polishing process, the slurry SL satisfies

MA/MB≦0.05 Equation (1)

wherein MA [mass ppm] is the content of the (A) component, and MB [mass ppm] is the content of the (A) component. In contrast, in the second polishing process, the slurry SL satisfies

0.07≦MA/MB<300 Equation (2).

Grounds for the component ratio in the above range will be described later in detail.

In the present embodiment, polyethylenimine (hereinafter briefly referred to as “PEI”) is used as the cationic water-soluble polymer, ferric nitrate is used as the iron nitrate, and colloidal silica grains are used as the abrasive grains.

(c) Preparation of CMP Apparatus

A CMP apparatus is then prepared. As described above, in the present embodiment, the slurry SL made of the same material is used, so that as long as the composition ratio can be changed in the process, it is possible to continuously conduct the first polishing process and the second polishing process using one CMP apparatus. An example of such a CMP apparatus is shown in a schematic perspective view of FIG. 2.

The CMP apparatus shown in FIG. 2 includes a polishing table 10, a polishing pad 12, a polishing table shaft 14, a nozzle 16, a top ring 20, and a top ring shaft 22.

The polishing table 10 is coupled to the polishing table shaft 14, and supports the polishing pad 12 on its upper surface. The polishing table 10 rotates, for example, in a rotation direction indicated by a mark AR1 when the polishing table shaft 14 is rotated by a drive mechanism D1 including, for example, a motor (not shown).

The top ring 20 is coupled to the top ring shaft 22, and presses the wafer W to the polishing pad 12 while holding the wafer W so that the surface of the polishing target faces the polishing pad 12.

The top ring 20 rotates, for example, in a rotation direction AR2 when the top ring shaft 22 is rotated by a drive mechanism D2 including, for example, a motor (not shown).

During polishing, the polishing table 10 rotates while the slurry SL is being supplied onto the polishing pad 12 by an unshown liquid supply control mechanism via the nozzle 16, and the top ring 20 rotates while pressing the wafer W to the polishing pad 12, whereby the polishing target surface of the wafer W is polished by the relative rotations of the polishing pad 12 and the wafer W.

The polishing pad 12 and the top ring 20 respectively rotate in the in directions of the marks AR1 and AR2 in the case shown in FIG. 2. It should however be understood that the polishing pad 12 and the top ring 20 do not rotate exclusively in these directions and may rotate in directions opposite to the above directions as long as the polishing pad 12 and the top ring 20 relatively rotate.

(d) Implementation of CMP

The polishing target shown in FIG. 1 is shown by way of example to more specifically describe a manufacturing method of a semiconductor device according to the present embodiment.

(i) First Polishing Process

First, the silicon wafer W is turned upside down and held to the top ring 20 (see FIG. 2) so that the tungsten oxide (WOx) film 46 faces the polishing pad 12.

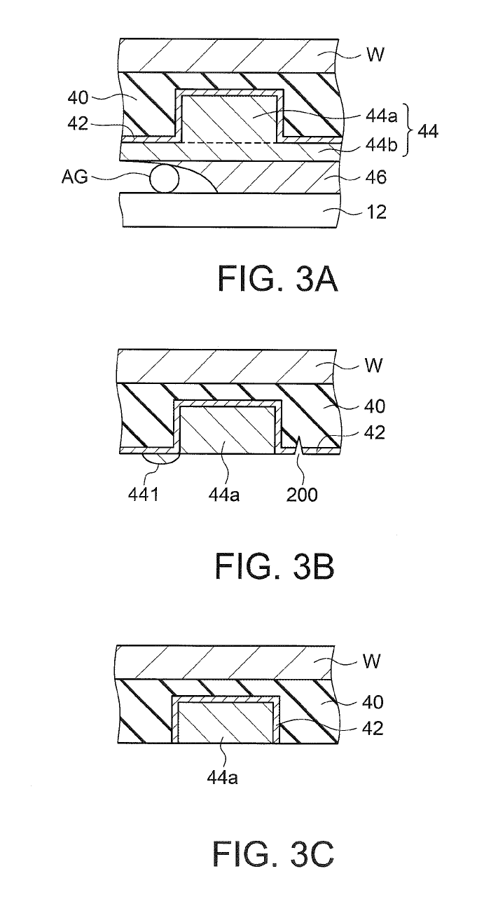

The polishing table shaft 14 is rotated (see the mark AR1 in FIG. 2) while a material in which MA/MB satisfies the relation of Equation (1) is being supplied onto the polishing pad 12 from the nozzle 16 as the slurry SL. The top ring 20 holding the silicon wafer W is brought closer to the polishing pad 12, and the top ring 20 is rotated while the wafer W is being pressed to the polishing pad 12 as shown in FIG. 3A. In this way, the tungsten oxide (WOx) film 46 and the bulk film 44b of tungsten are polished at a high speed. As a result, as shown in FIG. 3B, the tungsten oxide (WOx) film 46 is removed, and the barrier metal film 42 and the tungsten film 44a which is in the trench or the hole are exposed. In the example shown in FIG. 3B, a part 441 of the bulk film 44b remains unshaved, and a scratch 200 extending to the silicon oxide film 40 through the barrier metal film 42 is formed.

(ii) Second Polishing Process

The second polishing process which is a finishing process follows. Here, the supply of the slurry SL that satisfies the relation of Equation (1) is stopped, and the slurry SL that satisfies the relation of Equation (2) is supplied onto the polishing pad 12, whereby the tungsten film 44a and the silicon oxide film 40 are removed in the same selectivity so that the tungsten film alone remains in the wiring groove and the via hole as shown in FIG. 3C, desired wiring height is obtained, and planarity of the surface to be polished is ensured.

(iii) Grounds for Each Numerical Range

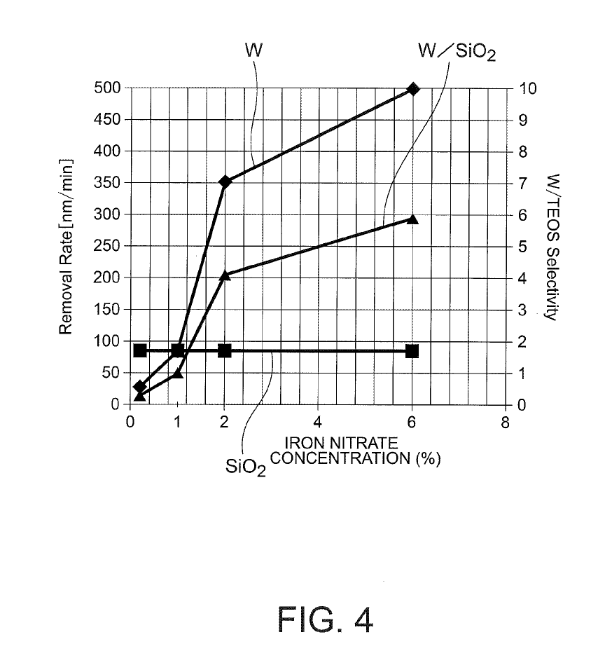

The reason for the change of the composition ratio of the materials of the slurry SL between the first polishing process and the second polishing process, and the grounds for each numerical range are described with reference to FIG. 4 to FIG. 13.

In the second polishing process, the tungsten film 44a, the barrier metal film 42, and the silicon oxide film 40 can be polished in the same selectivity by oxidizing the surface of tungsten and thus controlling the concentration of iron nitrate that becomes fragile. FIG. 4 shows an example of the selectivity of the tungsten/silicon oxide films obtained regarding a blanket wafer in the case where the concentration of ferric nitrate is changed.

As shown in FIG. 4, polishing performance required in each polishing process can be achieved on a blanket-wafer basis if the concentration of ferric nitrate in the first polishing process is 60,000 ppm (6%) and if the concentration of ferric nitrate in the second polishing process is 10,000 ppm (1%) (hereinafter referred to as a “pre-adjustment condition”).

However, an actual wafer in which various patterns are formed locally varies in the occupancy of metallic films depending on the pattern layout.

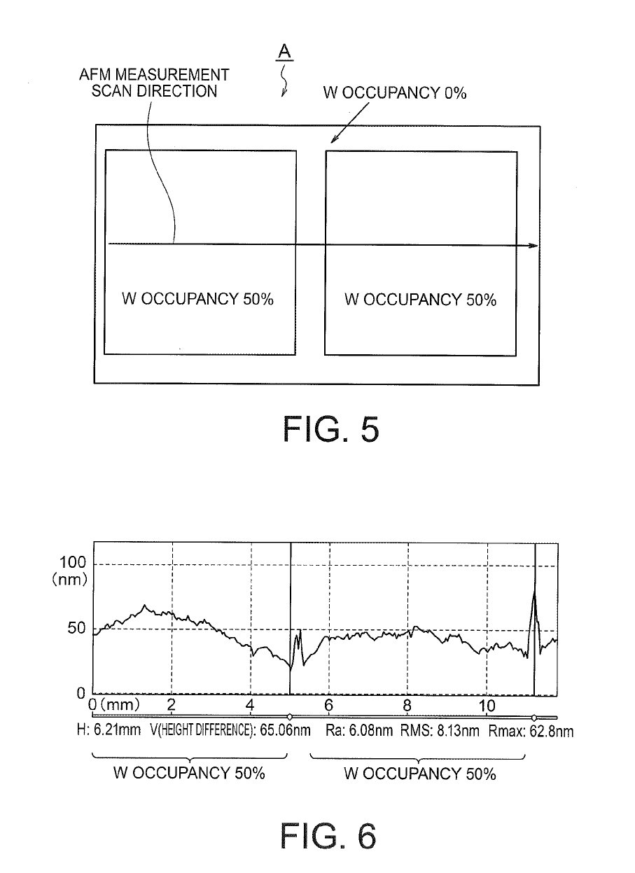

For example, a pattern layout “A” shown in FIG. 5 has regions in which tungsten films are formed with an occupancy of 50% across a narrow region containing no tungsten (the occupancy of W is 0%). When the second polishing process was conducted for such a pattern layout A in the aforementioned pre-adjustment condition and the height of the surface was inspected by, for example, an atomic force microscope (hereinafter briefly referred to as “AFM”), it was ascertained that the patterns in the part in which the occupancy was 50% were shaved about 65 nm more than the pattern in which the occupancy of W was 0%, for example, as indicated by “V: (height difference)” in FIG. 6.

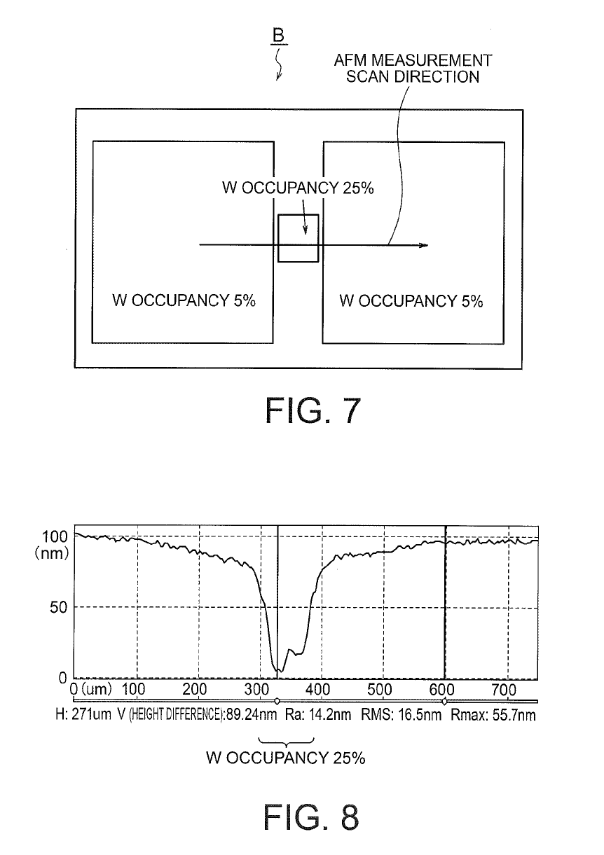

Moreover, for example, a pattern layout B shown in FIG. 7 has regions in which the occupancy of tungsten is relatively low (the occupancy of W is 5%) across a narrow region containing a relatively great amount of tungsten (the occupancy of W is 25%). When the second polishing process was conducted for such a pattern layout B in the aforementioned pre-adjustment condition and the height of the surface was inspected by the AFM in a similar manner, it was ascertained that the patterns in the part in which the occupancy was 25% were shaved about 90 nm more in some portions than the pattern in which the occupancy of W was 5%, for example, as indicated by “V: (height difference)” in FIG. 8.

It has thus been found that in the region in which loose and dense portions of patterns are scatteringly present, the occupancy of tungsten considerably changes, and a dent is generated in this part and leads to a large height difference. In the specification of the present application, the dent in the polished surface is referred to as “dishing”, and a height difference resulting from the dent is referred to as a “dishing amount”. The dishings shown by way of example in FIG. 6 and FIG. 8 are considered to be generated for the following reasons.

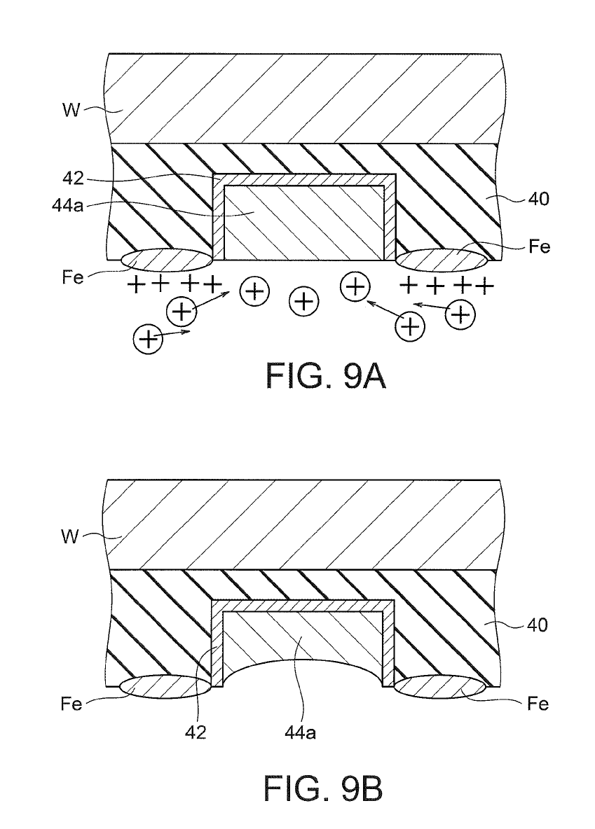

As shown in FIG. 9A, Fe ions in the slurry SL enter the silicon oxide film 40 in the second polishing process and adhere to the surface of the silicon oxide film 40, so that the zeta potential of the surface of the silicon oxide film 40 changes from a negative potential to a positive potential. In the meantime, the colloidal silica grains which have been turned to ph2 to have a positive zeta potential by, for example, 60,000 ppm of ferric nitrate repel the positive charge of the silicon oxide film 40 and thus concentrate on the tungsten film 44a. It is therefore considered that excessive polishing has taken place in the tungsten dense part as shown in FIG. 9B.

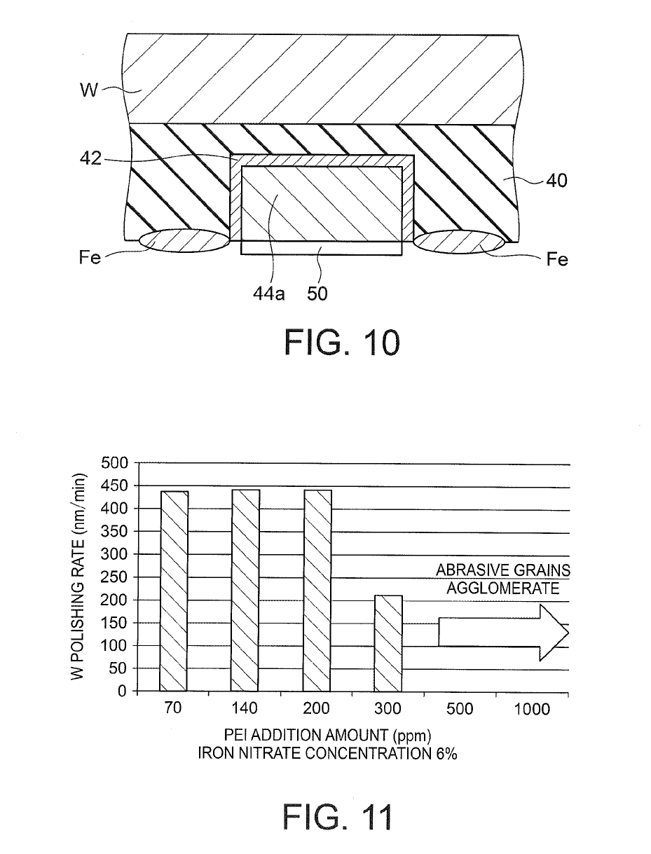

Therefore, in order to inhibit the excessive polishing of the tungsten film on the pattern, it is possible to inhibit the adhesion of Fe ions onto the silicon oxide film 40 and form a protective film which protects the tungsten film 44a. For example, as shown in FIG. 10, a protective film 50 is formed on the tungsten film 44a.

The protective film 50 can be made of PEI. Therefore, if a proper amount of PEI is added, the protective film 50 is satisfactorily formed on the tungsten film 44a so that the excessive polishing of the tungsten film 44a can be inhibited.

In contrast, if more than a proper amount of PEI is added, the polishing rate of the tungsten film decreases. An example of the relation between the PEI addition amount and the tungsten film polishing rate is shown in a graph of FIG. 11. The concentration of ferric nitrate is fixed at 60,000 ppm in the measurements in this example.

It has been ascertained from FIG. 11 that the polishing rate of tungsten does not change when the PEI addition amount ranges between 70 ppm and 200 ppm and that the polishing rate of tungsten decreases when the PEI addition amount is 300 ppm or more.

A proper range of the addition concentration of ferric nitrate is described here.

A high polishing rate needs to be maintained in the first polishing process. Regarding the addition concentration of ferric nitrate in the first polishing process, the polishing rate increases in response to the addition amount of ferric nitrate until the concentration of ferric nitrate reaches 60,000 ppm as shown in FIG. 4.

In the second polishing process, planarization needs to be finished while the dishing of the tungsten film is inhibited. The polishing rate increasing in response to the increase of the addition amount of ferric nitrate means that the dishing amount of the tungsten film is larger when the addition amount of ferric nitrate is larger.

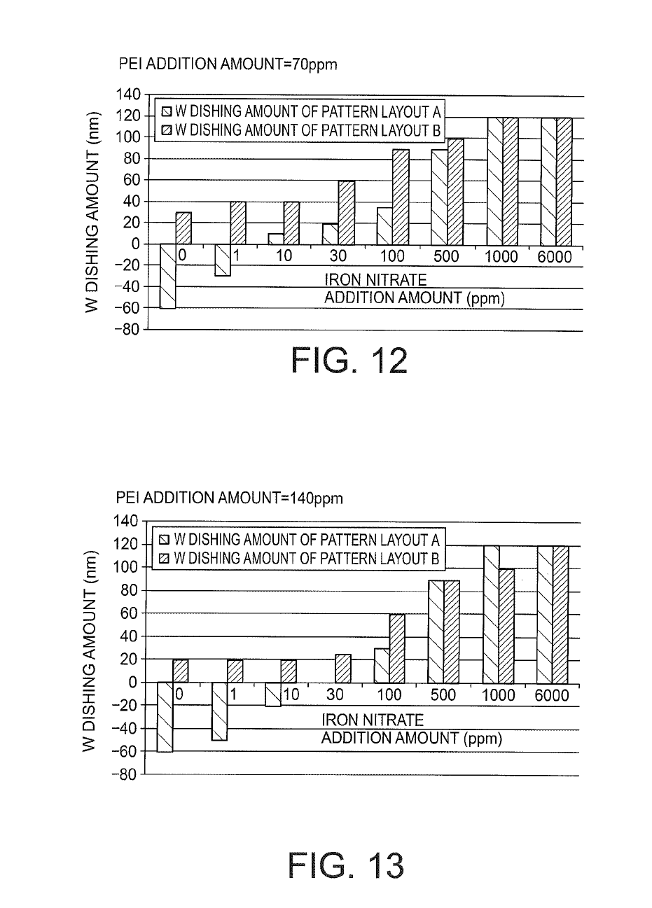

FIG. 12 and FIG. 13 are graphs obtained by measuring the dishing amounts of the tungsten film when the addition amount of ferric nitrate is changed after the PEI addition amount is fixed at 70 ppm and 140 ppm, respectively. The dishing amounts in FIG. 12 and FIG. 13 are the maximum values of height or maximum values of dents generated in the tungsten film 44a in parts of the respective pattern layouts A and B in which the occupancy changes. It is shown from FIG. 12 and FIG. 13 that the dishing of the tungsten film can be inhibited by the decrease of the addition amount of ferric nitrate in any PEI addition amount. In the meantime, it is also observed that when no ferric nitrate is added (0 ppm), the tungsten film 44a is not polished by contrast and that the surface to be polished is formed into a projecting shape instead in the pattern layout A in particular.

When FIG. 12 and FIG. 13 are compared with each other, it is also ascertained that the dishing amount in the case where the addition amount of ferric nitrate is changed in a PEI addition amount of 140 ppm in FIG. 13 is improved overall in comparison to the dishing amount generated in a PEI addition amount of 70 ppm in FIG. 12.

More specifically, it is found that when the addition amount of ferric nitrate is 6000 ppm, no difference of the dishing amount is seen between the pattern layouts A and B, but when the addition amount is 1000 ppm, the dishing amount of the pattern layout B in FIG. 13 is smaller than that in FIG. 12 and significantly decreases from 100 ppm. It is also observed that no difference of the dishing amount is seen between FIG. 12 and FIG. 13 up to 500 ppm, but when the addition amount is 100 ppm, the dishing amount in FIG. 13 is smaller than that in FIG. 12, and when the addition amount is 30 ppm, the dishing amount is 0, and a projecting shape is formed from 10 ppm instead.

Therefore, it is preferable that PEI is added in a range of 70 ppm to 300 ppm as is evident from FIG. 11, whereas ferric nitrate is controlled to 60,000 ppm or more in the first polishing process as is evident from FIG. 4, and ferric nitrate is controlled to 1 ppm or more and 100 ppm or less in the second polishing process as is evident from FIG. 13.

Thus, regarding the value of MA/MB which is the ratio between the content MA [mass ppm] of the cationic water-soluble polymer ((A) component) and the content MB [mass ppm] of the iron nitrate component ((B) component) in the slurry SL, the upper limit value is less than 300/60000=0.05 in the first polishing process, whereas the minimum value is 70/100=0.7 and the upper limit value is less than 300/1=300 in the second polishing process.

According to the manufacturing method of the semiconductor device in the present embodiment, by controlling the components of the slurry SL as described above, it is possible to highly efficiently polish the tungsten film in the first polishing process, and inhibit the dishing of the patterns that are high in occupancy during pattern polishing and still obtain satisfactory planarization performance in the second polishing process.

In addition, according to the manufacturing method of the semiconductor device in the present embodiment, it is possible to control the selectivity by only using the same kind of slurry without the change the kind of slurry and adjusting the composition ratio of the materials contained in the slurry, which eliminates the risk of, for example, the variation of polishing characteristics caused by the mixture of slurries having different compositions, and slurry agglomeration. As a result, it is possible to continuously conduct the first polishing process and the second polishing process on a single polishing table without using two polishing tables, and obtain low-cost, high-efficiency, and satisfactory planarization performance.

Furthermore, according to the slurry in the present embodiment, the selectivity of the polishing target can be controlled only by the adjustment of the composition ratio of the contained materials, so that it is possible to achieve low-cost, high-efficiency, and satisfactory planarization.

### (2) Embodiment 2

In the present embodiment, the slurry SL according to Embodiment 1 is used in polishing, and a urethane foam pad is used as the polishing pad 12 at the time of polishing.

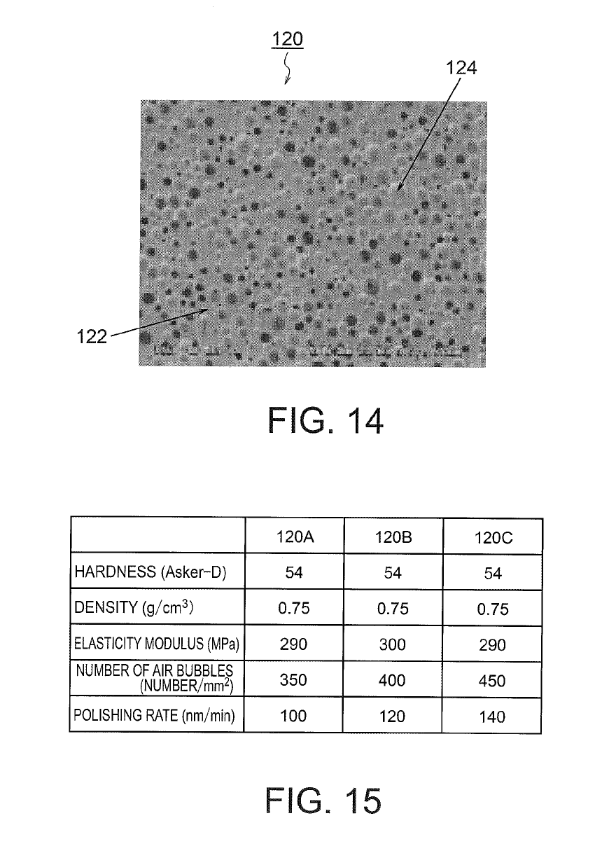

FIG. 14 is an example of a schematic diagram showing the planar shape of an example of a urethane foam pad 120 used in the present embodiment. The urethane foam pad 120 has a large number of air bubbles (pores) 124 formed in the surface of a base material 122 made of, for example, a polyester felt. The retention performance of the slurry SL is improved by the air bubbles 124 contained in the surface of the polishing pad.

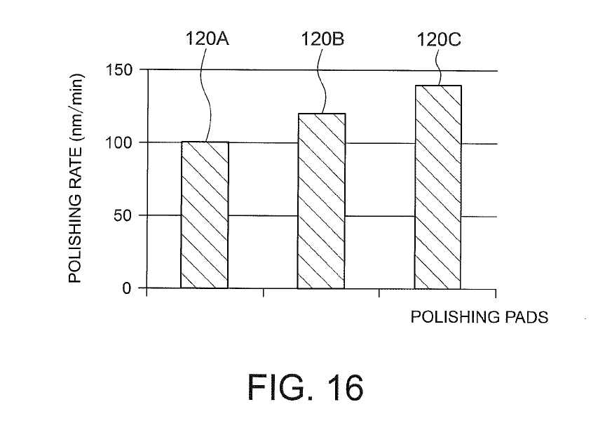

When the density of the polishing pad is constant, the surface area of the polishing pad increases by the increase of the number of air bubbles per unit area, so that the retention performance of the slurry is more improved. FIG. 15 is an example of a table in which the characteristics of three polishing pads 120A to 120C having a fixed value of density and varying in the number of air bubbles per unit area are examined. FIG. 16 is an example of a graph showing examples of polishing rates at which CMP is conducted by use of the respective polishing pads 120A to 120C. It is found from FIG. 15 and FIG. 16 that the polishing pads having a larger number of air bubbles per unit area are higher in the retention performance of the slurry and can achieve higher polishing rates.

According to the manufacturing method of the semiconductor device in the present embodiment, CMP is conducted by use of the urethane foam pad 120 having a large number of air bubbles 124 formed in the surface, so that it is possible to planarize the film to be polished at a high polishing rate.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A manufacturing method of a semiconductor device comprising:
using a slurry containing a cationic water-soluble polymer (A), iron nitrate (B), and abrasive grains (C) to chemically and mechanically polish a film to be polished, the film comprising an insulating film provided with a groove or a hole, and a tungsten film to fill the groove or the hole,
wherein the chemical mechanical polishing comprises a first polishing process to polish the tungsten film, and a second polishing process to polish the tungsten film and the insulating film together, the second polishing process being conducted after the first polishing process, and
the content of the (A) component in the slurry used in the second polishing process is less than 300 ppm, and the content of the (B) component is 100 ppm or less.

2. The method of claim 1,
wherein the content of the (A) component in the slurry used in the second polishing process is 70 ppm or more.

3. The method of claim 1,
wherein the content of the (B) component in the slurry used in the first polishing process is 60000 ppm or more.

4. The method of claim 1,
wherein the content of the (B) component in the slurry used in the second polishing process is 1 ppm or more.

5. The method of claim 1,
wherein the chemical mechanical polishing is conducted by use of a polishing pad which comprises air bubbles formed in the surface thereof.

6. A manufacturing method of a semiconductor device comprising:
using a slurry containing a cationic water-soluble polymer (A), iron nitrate (B), and abrasive grains (C) to chemically and mechanically polish a film to be polished, the film comprising an insulating film provided with a groove or a hole, and a tungsten film to fill the groove or the hole,
wherein the chemical mechanical polishing comprises first polishing to polish the tungsten film, and second polishing to polish the tungsten film and the insulating film together, the second polishing being conducted after the first polishing, and
the second polishing comprises forming a protective film made of the cationic water-soluble polymer on the tungsten film in the groove or the hole.

7. The method of claim 6,
wherein the content of the (A) component in the slurry used in the second polishing process is in a range of 70 ppm to 300 ppm.

8. The method of claim 6,
wherein the content of the (B) component in the slurry used in the second polishing process is in a range of 1 ppm to 100 ppm.

9. The method of claim 6,
wherein the content of the (B) component in the slurry used in the first polishing process is 60000 ppm or more.

10. The method of claim 6,
wherein the chemical mechanical polishing is conducted by use of a polishing pad which comprises air bubbles formed in the surface thereof.

11. The method of claim 6,
wherein the protective film is formed by use of polyethylenimine.

12. A chemical mechanical polishing slurry used to simultaneously polish an insulating film and tungsten provided on a substrate, the slurry comprising
a cationic water-soluble polymer (A), iron nitrate (B), and abrasive grains (C),
wherein the content of the (A) component is less than 300 ppm, and the content of the (B) component is 100 ppm or less.
